(19) United States
(12) Patent Application Publication
(10) Pub. No.: US 2004/0119133 A1
(43) Pub. Date: Jun. 24, 2004

(54) Semiconductor device

(75) Inventor: Toshiaki Iwamatsu, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/406,289

(22) Filed: Apr. 4, 2003

(30) Foreign Application Priority Data
Dec. 18, 2002 (JP) 2002-366550

(51) Int. Cl. H01L 29/00

(52) U.S. Cl. 257/506

(57) ABSTRACT

A semiconductor device which enables an improvement of a current driving capability of a MOS transistor sufficiently is attained.

A chamfering is performed at corners of source/drain active layers of a MOS transistor in a plane view of a surface of a semiconductor substrate. By this chamfering, obtuse angles come to be included in a boundary between the source/drain active layers and an element isolation region. As a result, an acute part is not generated in the corners, and a stress added to the source/drain active layers from the element isolation region is relaxed. Thus, an effect that this stress has upon an electric characteristic of the MOS transistor can be reduced, and the MOS transistor that the current driving capability is sufficiently improved is attainable.

### BACKGROUND OF THE INVENTION

1. Field of the Invention

The present invention relates to a semiconductor device formed on a surface of a semiconductor substrate.

2. Description of the Background Art

A MOS(Metal Oxide Semiconductor) transistor is mentioned as a semiconductor device formed on a surface of a semiconductor substrate, for example. The MOS transistor has a gate electrode as a control electrode formed on the semiconductor substrate and source/drain active layers which are formed in positions adjacent to the gate electrode in the surface of the semiconductor substrate. In the surface of the semiconductor substrate, an element isolation region surrounding the source/drain active layers is formed of an oxide film etc., and shapes of the source/drain active layers are determined by the element isolation region.

Information of conventional art documents relating to the invention of the present application is described below.

Japanese Patent Application Laid-Open No. 2002-134374

Japanese Patent Application Laid-Open No. 1997-153603

G. Scott et al., “NMOS Drive Current Reduction Caused by Transistor Layout and Trench Isolation Induced Stress”, (U.S.A.), IEDM, 1999

The source/drain active layers are generally formed into rectangular shapes in a plane view of the surface of the semiconductor substrate. Thus, considering both the source side and drain side, the source/drain active layers and the element isolation region are in contact with each other at a boundary including four corner parts.

However, also described in IEDM, 1999 described above according to a miniaturization of a semiconductor device, a stress which is added to the source/drain active layers from an end part of the element isolation region (in other words, the boundary part between the source/drain active layers and the element isolation region) increases, and this stress has an effect upon an electric characteristic in the MOS transistor. Especially, the stress has a large effect in the corner part of the source/drain active layers, and this stress causes a decrease of carrier mobility and an increase of a leakage current at a drain-body junction and thus has a large effect upon the electric characteristic of the MOS transistor.

Thus, even if an effort to improve current driving capability is put into the MOS transistor, there is a case that the purpose is not sufficiently attained by reason of the stress in the corner part.

### SUMMARY OF THE INVENTION

Hereupon, it is an object of the present invention to attain a semiconductor device which enables an improvement of a current driving capability of a MOS transistor sufficiently.

According to an aspect of the present invention, a semiconductor device has a MIS (Metal Insulator Semiconductor) transistor including source/drain active layers formed in a surface of a semiconductor substrate and an element isolation region formed adjacent to the source/drain active layers in the surface of the semiconductor substrate.

In a plane view of the surface of the semiconductor substrate, the source/drain active layers and the element isolation region are in contact with each other at a boundary including at least one obtuse angle or one curve.

The obtuse angle or the curve constitutes a chamfering shape at a corner part of the source/drain active layers in a plane view of the surface of the semiconductor substrate.

In the plane view of the surface of the semiconductor substrate, the source/drain active layers and the element isolation region are in contact with each other at the boundary including at least one obtuse angle or one curve. Thus, an acute part is not generated in the corner of the source/drain active layers, a stress added to the source/drain active layers from the element isolation region is relaxed at the part of the obtuse angle or the curve in the boundary, and thus an effect upon an electric characteristic of the semiconductor device can be reduced. According to this, the MIS transistor whose current driving capability is sufficiently improved is attainable.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top surface view illustrating a semiconductor device according to a preferred embodiment.

FIG. 2 is a cross sectional view illustrating the semiconductor device according to the preferred embodiment.

FIGS. 3 to 5 are top surface views all illustrating the other example of the semiconductor device according to the preferred embodiment.

### DESCRIPTION OF THE PREFERRED EMBODIMENTS

In the preferred embodiment according to the present invention, a stress added to source/drain active layers from an element isolation region at corners is relaxed by planing off the corners of the source/drain active layers and make them be obtuse shapes.

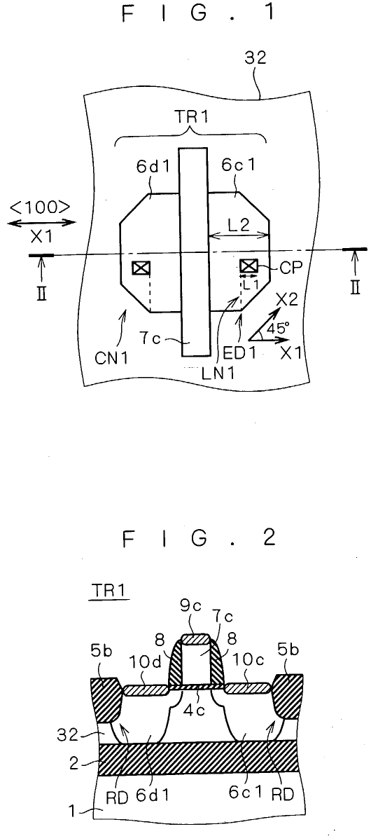

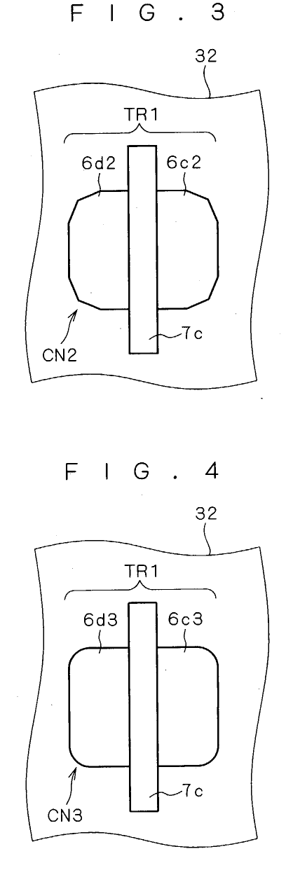

FIGS. 1 and 2 are drawings both illustrating a MOS transistor TR1 which is a semiconductor device according to the present preferred embodiment. FIG. 2 is the drawing illustrating a cross section along the section line II-II in FIG. 1.

As shown in FIG. 2, in the present preferred embodiment, the MOS transistor TR1 is formed on a semiconductor substrate which includes a support substrate 1 composed of a silicon substrate, an oxide film layer 2 and a SOI (Semiconductor On Insulator or Silicon On Insulator) layer 32.

Moreover, in FIG. 2, a gate insulating film 4c below a gate electrode 7c, a sidewall insulating film 8 by the side of the gate electrode 7c, silicidation regions 9c, 10c and 10d on the gate electrode 7c and on source/drain active layers 6c1 and 6d1 and an element isolation region 5b adjacent to the source/drain active layers 6c1 and 6d1.

As shown in FIG. 1, with regard to this MOS transistor TR1, chamferings CN1 are performed at the corners of the source/drain active layers 6c1 and 6d1 in a plane view of the surface of the semiconductor substrate. By this chamfering CN1, obtuse angles are included in a boundary between the source/drain active layers 6c1 and 6d1 and the element isolation region 5b. As a result, an acute part is not generated in the corners, and the stress added to the source/drain active layers 6c1 and 6d1 from the element isolation region 5b is relaxed.

Thus, an effect upon an electric characteristic of the MOS transistor TR1 can be reduced, and the MOS transistor whose current driving capability is sufficiently improved is attainable.

Besides, a channel direction of the MOS transistor TR1 is placed parallel with a crystal direction <100> in the SOI layer 32, shown as a direction X1 in FIG. 1. It is recognized that by placing the channel direction parallel with the crystal direction <100>, the current driving capability of a P channel MOS transistor is improved by approximately fifteen percent, and moreover, a short channel effect becomes small, too.

It is thought that the reason why the current driving capability is improved is that a mobility of a hole in the crystal direction <100> is higher than that in a crystal direction <110>, and the reason why the short channel effect becomes small is that a diffusion coefficient value of Boron in the crystal direction <100> is smaller than that in the crystal direction <110>.

Moreover, with regard to a shape of the chamferings CN1, the cutting surfaces may be parallel with a direction X2 which shifts from the direction X1 parallel with the channel direction by 45°.

The method below can be employed to attain the active layers having the chamfering shapes CN1 at the corner such as the source/drain active layers 6c1 and 6d1.

The element isolation region 5b is generally formed using a photolithography technique, a thermal oxidation technique and a trench embedding technique. In them, when the shape of the element isolation region 5b is determined by the photolithography technique, a pattering shape of a photoresist (a shape of the part where the photoresist remains) formed on the substrate is set to be the chamfering shape, the same as the source/drain active layers 6c1 and 6d1.

Doing so, the part except for the part where the photoresist covers can be formed to be the element isolation region by a thermal oxidation method, for example. Afterwards, by removing the photoresist and implanting an impurity into the part surrounded with the element isolation region, the source/drain active layers 6c1 and 6d1 can be formed to have the chamfering shapes CN1 at the corners, as shown in FIG. 1.

Besides, as shown in FIG. 2, with regard to this MOS transistor TR1, chamferings RD are also performed at the corners between the source/drain active layers 6c1, 6d1 and the element isolation region 5b in a thickness direction of the semiconductor substrate. In other words, a curve part is included in the boundary between the source/drain active layers 6c1 and 6d1 and the element isolation region 5b. By performing this chamferings RD, the acute part is not generated in the corner, and the stress added to the source/drain active layers 6c1 and 6d1 from the element isolation region 5b is relaxed.

Thus, an effect of the stress upon an electric characteristic of the MOS transistor TR1 can be reduced more, and the MOS transistor that a current driving capability is sufficiently improved is attainable.

To perform the chamferings RD at the corners between the source/drain active layers 6c1, 6d1 and the element isolation region 5b in the thickness direction of the semiconductor substrate, the element isolation region 5b may be formed by the thermal oxidation method as described above, for example. As known generally, when the thermal oxidation method is employed, the corner parts of the element isolation region 5b come to have a roundish shape. According to this, the source/drain active layers 6c1, 6d1 and the element isolation region 5b come to be in contact with each other at the boundary including the curves. Besides, it may be also employed that they are in contact with each other at the boundary including at least one obtuse angle except for the curve (for example, in a case of forming the element isolation region 5b in a trench having a taper etc.).

In the present preferred embodiment, the chamfering CN1 is performed at the corners, thus the area of the source/drain active layers 6c1 and 6d1 is reduced a little as compared with a case that the chamfering CN1 is not performed. When the area of the source/drain active layers 6c1 and 6d1 is reduced, the number of contact plugs which are able to connect with the source/drain active layers 6c1 and 6d1 is reduced, thus an increase of a contact resistance between the active layers and the plugs may be concerned.

However, if the silicadation regions 10c and 10d are formed on surfaces of the source/drain active layers 6c1 and 6d1, the increase of the contact resistance can be sufficiently controlled.

It may be employed that a width L2 of the source/drain active layers 6c1 and 6d1 is appropriately three times as wide as a width L1 of a contact plug CP or more, for example. By forming the width L2 of the source/drain active layers 6c1 and 6d1 wide in this extent, a contact defect can hardly occur. In other words, even in case that an alignment of the contact plug CP and the source/drain active layers 6c1 and 6d1 with each other slips to a small extent by an influence of a slippage of a photomask when forming the MOS transistor TR1 using the photolithography technique etc., the possibility that the contact plug CP is formed beyond the source/drain active layers 6c1 and 6dl can be lowered.

It may not be employed that a position of an end part ED1 in the cutting surface of the chamfering CN1 at the side of the gate electrode 7c is placed close to the gate electrode 7c beyond an extension line LN1 of the end part of the contact plug CP at the side of the gate electrode 7c. It is because the possibility that the contact resistance increases by reason of a decrease of the area of the source/drain active layers 6c1 and 6d1, and the possibility that the contact plug CP is formed beyond the source/drain active layers 6c1 and 6d1 rises.

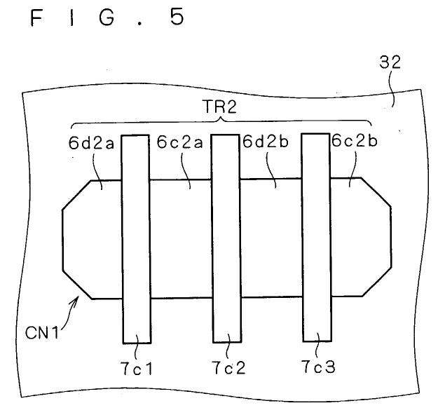

Besides, in FIG. 1, the chamfering CN1 at the corners of the source/drain active layers 6c1 and 6d1 is illustrated as a straight shape, however, it is not limited to such a shape as this, of course. For example, a chamfering CN2 of a polygonal line shape as shown in FIG. 3 and a chamfering CN3 of a curved line shape as shown in FIG. 4 are also applicable.

Besides, in the present preferred embodiment, the chamfering at the corners of the source/drain active layer of the MOS transistor TR1 is described, however, the present invention is also applicable to the other semiconductor device except for the MOS transistor. In other words, with regard to the semiconductor device using the active layer formed in the surface of the semiconductor substrate such as a capacitor using a MOS structure, a capacitor using a PN junction, etc., the effect upon the electric characteristic can be reduced by performing the chamfering at the corners included in the boundary between the active layer and the element isolation region.

Besides, the present application of the invention is also applicable to an aggregate TR2 of the transistors having a structure that plural gate electrodes 7c1 to 7c3 are formed in parallel, and that source/drain active layers 6d2a, 6c2a, 6d2b and 6c2b are formed between the respective gate electrodes and in adjacent parts of the gate electrodes of both ends. In this case, the corner does not exist at the boundary between the active layer and the element isolation region as described above in the source/drain active layers 6c2a and 6d2b between the respective gate electrodes, thus it may be employed to perform the chamfering at the mere corners of the source/drain active layers 6d2a and 6c2b of both ends.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a MIS (Metal Insulator Semiconductor) transistor which includes source/drain active layers formed in a surface of a semiconductor substrate; and
an element isolation region which is formed adjacent to said source/drain active layers in said surface of said semiconductor substrates; wherein
in a plane view of said surface of said semiconductor substrate, said source/drain active layers and said element isolation region are in contact with each other at a boundary including at least one obtuse angle or one curve, and
said obtuse angle or said curve constitutes a chamfering shape at a corner part of said source/drain active layers in a plane view of said surface of said semiconductor substrate.

2. The semiconductor device according to claim 1, wherein
said source/drain active layer and said element isolation region are also in contact with each other at a boundary including at least one obtuse angle or one curve in a thickness direction of said semiconductor substrate.
